(19) United States
(12) Patent Application Publication
(10) Pub. No.: US 2026/0311740 A1
(43) Pub. Date: Oct. 8, 2026

(54) MEMORY THAT DETERMINES LAST PROGRAMMED WORD LINE, STORAGE DEVICE AND OPERATING METHOD OF THE MEMORY

(71) Applicant: SK hynix Inc., Icheon-si (KR)

(72) Inventor: Gun Soo LEE, Icheon-si (KR)

(21) Appl. No.: 19/306,188

(22) Filed: Aug. 21, 2025

(30) Foreign Application Priority Data
Apr. 4, 2025 (KR) 10-2025-0043803

(51) Int. Cl. G11C 11/408

(52) U.S. Cl. CPC G11C 11/4085

(57) ABSTRACT

The memory includes N number of word lines, M number of bit lines, memory cells each corresponding to one of the N number of word lines and one of the M number of bit lines, and a control logic determining a target word line, among the N number of word lines, based on a voltage of a target bit line while a first word line voltage or a second word line voltage is applied to each of the N number of word lines.

### CROSS-REFERENCE TO RELATED APPLICATION

The present application claims priority under 35 U.S.C. §119(a) to Korean patent application number 10-2025-0043803 filed in the Korean Intellectual Property Office on Apr. 4, 2025, which is incorporated herein by reference in its entirety.

### BACKGROUND

### 1. Technical Field

Embodiments of the present disclosure relate to a memory for determining a last programmed word line, a storage device, and a method of operating the memory.

### 2. Related Art

A storage device is a device for storing data according to a request from an external device such as a computer, a mobile terminal (e.g., a smart phone or tablet), or the like.

A storage device may include a memory for storing data therein and a controller for controlling the memory. The memory may be a volatile memory or a non-volatile memory. The controller may receive a command from an external device (i.e., a host), and execute or control operations to read, write, or erase data in the memory included in the storage device according to the received command.

Meanwhile, when a write operation of the storage device to a memory is interrupted by an external factor (e.g., SPO (Sudden Power Off)), information on a location where data was last written in the memory may be lost. In this case, the storage device may need to re-search for the location where the data was last written in the memory.

A conventional storage device searches for the location where data was last written by repeatedly reading data stored in the memory. Accordingly, the storage device consumes a significant amount of time to perform the search.

### SUMMARY

Embodiments of the present disclosure may provide a memory, a storage device, and a method of operating the memory that may efficiently search for a target word line, which is a last programmed word line, by omitting an operation of repeatedly reading data programmed in the memory.

Objects of embodiments of the present disclosure are not limited to those set forth herein, and other unmentioned objects will be apparent to those skilled in the art from the following description.

Embodiments of the present disclosure may provide a memory comprising N number of word lines, M number of bit lines, a plurality of memory cells each corresponding to one of the N number of word lines and one of the M number of bit lines, and control logic determining a target word line, which is a word line programmed last from among the N number of word lines. The control logic may determine the target word line based on a voltage of a target bit line when a first word line voltage or a second word line voltage is applied to each of the N number of word lines.

Embodiments of the present disclosure may provide a storage device comprising a memory including N number of word lines, M number of bit lines, and a plurality of memory cells each corresponding to one of the N number of word lines and one of the M number of bit lines, the memory determining a target word line, which is a word line programmed last from among the N number of word lines; and a controller for transmitting a command requesting information about the target word line to the memory. The memory may determine the target word line based on a voltage of a target bit line when a first word line voltage or a second word line voltage is applied to each of the N number of word lines. The memory may transmit a parameter indicating the information about the target word line to the controller in response to the command.

Embodiments of the present disclosure may provide a method of operating a memory, the method comprising: applying a first word line voltage or a second word line voltage to each of N number of word lines; determining a voltage of a target bit line among M number of bit lines; and determining a target word line, which is a word line programmed last from among the N number of word lines, based on the voltage of the target bit line.

According to embodiments of the present disclosure, a memory, a storage device, and a method of operating the memory may be provided that may efficiently search for a last programmed word line by omitting an operation of repeatedly reading data programmed in the memory.

The effects of the present disclosure are not limited to the foregoing objects, and other effects will be apparent to those skilled in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 illustrates a storage device according to an embodiment of the present disclosure.

FIG. 2 illustrates a memory of FIG. 1.

FIG. 3 illustrates a schematic operation of a memory according to an embodiment of the present disclosure.

FIG. 4 illustrates states of memory cells according to an embodiment of the present disclosure.

FIG. 5 illustrates a schematic operation for determining a target word line by a memory according to an embodiment of the present disclosure.

FIGS. 6 and 7 illustrate examples of an operation for determining a target word line by a memory according to an embodiment of the present disclosure.

FIG. 8 is a flowchart illustrating an example of an operation for determining a target word line by a memory according to an embodiment of the present disclosure.

FIG. 9 illustrates a schematic operation of a storage device according to an embodiment of the present disclosure.

FIG. 10 illustrates a method of operating a memory according to an embodiment of the present disclosure.

### DETAILED DESCRIPTION

Hereinafter, embodiments of the present disclosure are described in detail with reference to the accompanying drawings. Throughout the specification, reference to “an embodiment,” “another embodiment” or the like is not necessarily to only one embodiment, and different references to any such phrase are not necessarily limited to the same embodiment(s). The term “embodiments” when used herein does not necessarily refer to all embodiments.

Various embodiments of the present invention are described below in more detail with reference to the accompanying drawings. However, the present invention may be embodied in different forms and variations, and should not be construed as being limited to the embodiments set forth herein. Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing methods herein.

When implemented at least partially in software, the controllers, processors, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device.

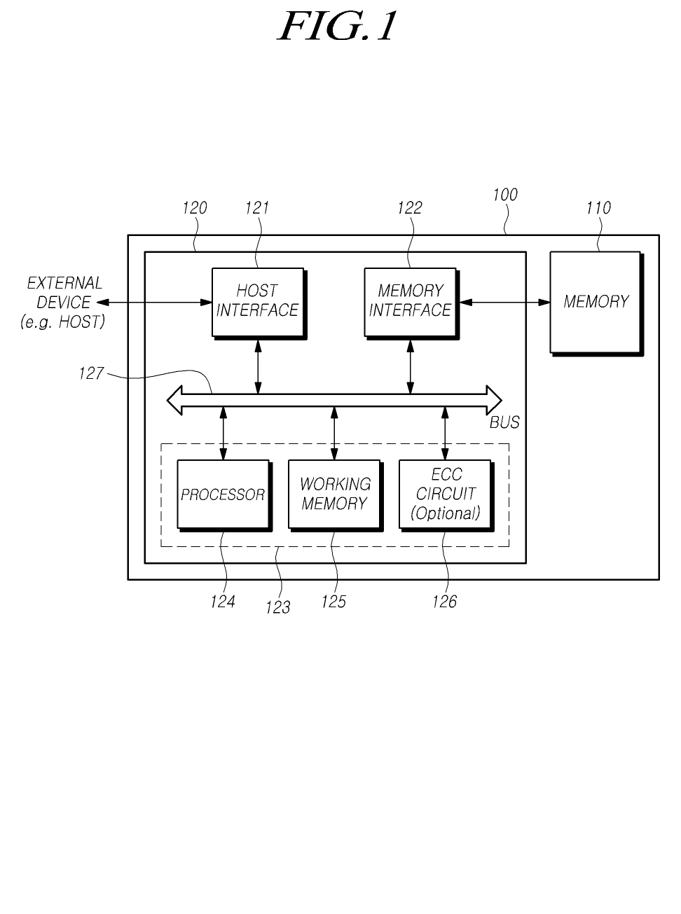

FIG. 1 illustrates a storage device 100 according to an embodiment of the present disclosure.

Referring to FIG. 1, the storage device 100 may include a memory 110 that stores data and a controller 120 that controls the memory 110.

The memory 110 includes a plurality of memory blocks, and operates under the control of the controller 120. Operations of the memory 110 may include, for example, a read operation, a program operation (also referred to as a write operation) and an erase operation.

The memory 110 may include a memory cell array including a plurality of memory cells (also simply referred to as “cells”) that store data.

For example, the memory 110 may be realized in various types of memory such as a DDR SDRAM (double data rate synchronous dynamic random access memory), an LPDDR4(low power double data rate 4) SDRAM, a GDDR (graphics double data rate) SDRAM, an LPDDR (low power DDR), an RDRAM (Rambus dynamic random access memory), a NAND flash memory, a 3D NAND flash memory, a NOR flash memory, a resistive random access memory (RRAM), a phase-change memory (PRAM), a magnetoresistive random access memory (MRAM), a ferroelectric random access memory (FRAM), a spin transfer torque random access memory (STT-RAM), and so forth.

The memory 110 may be implemented as a three-dimensional array structure. For example, embodiments of the present disclosure may be applied to a charge trap flash (CTF) in which a charge storage layer is configured by a dielectric layer and a flash memory in which a charge storage layer is configured by a conductive floating gate.

The memory 110 may receive a command and an address from the controller 120 and may access an area in the memory cell array that is selected by the address. In other words, the memory 110 may perform an operation indicated by the command, on the area selected by the address.

The memory 110 may perform a program operation, a read operation or an erase operation. For example, when performing the program operation, the memory 110 may program data to the area selected by the address. When performing the read operation, the memory 110 may read data from the area selected by the address. In the erase operation, the memory 110 may erase data stored in the area selected by the address.

The controller 120 may control write (or program), read, erase and background operations for the memory 110. For example, background operations may include at least one from among a garbage collection (GC) operation, a wear leveling (WL) operation, a read reclaim (RR) operation, a bad block management (BBM) operation, and so forth.

The controller 120 may control the operation of the memory 110 according to a request from a device (e.g., a host) located outside the storage device 100. The controller 120, however, also may control the operation of the memory 110 regardless of a request from the host.

The host may be a computer, an ultra-mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a computer network, one of various electronic devices configuring a telematics network, an RFID (radio frequency identification) device, and a mobility device (e.g., a vehicle, a robot or a drone) capable of driving under human control or autonomous driving, as non-limiting examples. Alternatively, the host may be a virtual reality (VR) device providing 2D or 3D virtual reality images or an augmented reality (AR) device providing augmented reality images. The host may be any one of various electronic devices that require the storage device 100 capable of storing data.

The host may include at least one operating system (OS). The operating system may generally manage and control the function and operation of the host, and may control interoperability between the host and the storage device 100. The operating system may be classified into a general operating system and a mobile operating system depending on the mobility of the host.

The controller 120 and the host may be devices that are separated from each other, or the controller 120 and the host may be integrated into one device. Hereunder, for the sake of convenience in explanation, descriptions will describe the controller 120 and the host as devices that are separated from each other.

Referring to FIG. 1, the controller 120 may include a memory interface 122 and a control circuit 123, and may further include a host interface 121.

The host interface 121 provides an interface for communication with the host. For example, the host interface 121 provides an interface that uses at least one from among various interface protocols such as a USB (universal serial bus) protocol, an MMC (multimedia card) protocol, a PCI (peripheral component interconnection) protocol, a PCI-E (PCI-express) protocol, an ATA (advanced technology attachment) protocol, a serial-ATA protocol, a parallel-ATA protocol, an SCSI (small computer system interface) protocol, an ESDI (enhanced small disk interface) protocol, an IDE (integrated drive electronics) protocol and a private protocol.

When receiving a command from the host, the control circuit 123 may receive the command through the host interface 121, and may perform an operation of processing the received command.

The memory interface 122 may be coupled with the memory 110 to provide an interface for communication with the memory 110. That is to say, the memory interface 122 may be configured to provide an interface between the memory 110 and the controller 120 under the control of the control circuit 123.

The control circuit 123 performs the general control operations of the controller 120 to control the operation of the memory 110. To this end, for instance, the control circuit 123 may include at least one of a processor 124 and a working memory 125, and may optionally include an error detection and correction circuit (ECC circuit) 126.

The processor 124 may control general operations of the controller 120, and may perform a logic calculation. The processor 124 may communicate with the host through the host interface 121, and may communicate with the memory 110 through the memory interface 122.

The processor 124 may execute logical operations required to perform the function of a flash translation layer (FTL). The processor 124 may translate a logical block address (LBA), provided by the host, into a physical block address (PBA) through the flash translation layer. The flash translation layer may receive the logical block address and translate the logical block address into the physical block address, by using a mapping table.

There are various address mapping methods of the flash translation layer, depending on a mapping unit. Typical address mapping methods include a page mapping method, a block mapping method and a hybrid mapping method.

The processor 124 may randomize data received from the host. For example, the processor 124 may randomize data received from the host by using a set randomizing seed. The randomized data may be provided to the memory 110, and may be programmed to a memory cell array of the memory 110.

In a read operation, the processor 124 may derandomize data received from the memory 110. For example, the processor 124 may derandomize data received from the memory 110 by using a derandomizing seed. The derandomized data may be outputted to the host.

The processor 124 may execute firmware to control the operation of the controller 120. Namely, in order to control the general operation of the controller 120 and perform a logic calculation, the processor 124 may execute (or drive) firmware loaded in the working memory 125 upon booting. Hereafter, an operation of the storage device 100 according to embodiments of the disclosure will be described as implementing a processor 124 that executes firmware in which the corresponding operation is defined.

Firmware, as a program to be executed in the storage device 100 to drive the storage device 100, may include various functional layers. For example, the firmware may include binary data in which codes for executing the functional layers, respectively, are defined.

For example, the firmware may include at least one from among a flash translation layer, which performs a translating function between a logical address requested to the storage device 100 from the host and a physical address of the memory 110, a host interface layer (HIL), which serves to analyze a command requested to the storage device 100 as a storage device from the host and transfer the command to the flash translation layer, and a flash interface layer (FIL), which transfers a command, instructed from the flash translation layer, to the memory 110.

Such firmware may be loaded in the working memory 125 from, for example, the memory 110 or a separate nonvolatile memory (e.g., a ROM or a NOR Flash) located outside the memory 110. The processor 124 may first load all or a part of the firmware in the working memory 125 when executing a booting operation after power-on.

The processor 124 may perform a logic calculation, which is defined in the firmware loaded in the working memory 125, to control the general operation of the controller 120. The processor 124 may store a result of performing the logic calculation defined in the firmware, in the working memory 125. The processor 124 may control the controller 120 according to a result of performing the logic calculation defined in the firmware such that the controller 120 generates a command or a signal. When a part of firmware, in which a logic calculation to be performed is defined, is stored in the memory 110, but not loaded in the working memory 125, the processor 124 may generate an event (e.g., an interrupt) for loading the corresponding part of the firmware into the working memory 125 from the memory 110.

The processor 124 may load metadata necessary for driving firmware from the memory 110. The metadata, as data for managing the memory 110, may include for example management information on user data stored in the memory 110.

Firmware may be updated while the storage device 100 is manufactured or while the storage device 100 is operating. The controller 120 may download new firmware from the outside of the storage device 100 and update existing firmware with the new firmware.

To drive the controller 120, the working memory 125 may store necessary firmware, a program code, a command and data. The working memory 125 may be a volatile memory that includes, for example, at least one from among an SRAM (static RAM), a DRAM (dynamic RAM) and an SDRAM (synchronous DRAM). Meanwhile, the controller 120 may additionally use a separate volatile memory (e.g., SRAM, DRAM) located outside the controller 120 in addition to the working memory 125.

The error detection and correction circuit 126 may detect an error bit of target data, and correct the detected error bit by using an error correction code. The target data may be, for example, data stored in the working memory 125 or data read from the memory 110.

The error detection and correction circuit 126 may decode data by using an error correction code. The error detection and correction circuit 126 may be realized by various code decoders. For example, a decoder that performs unsystematic code decoding or a decoder that performs systematic code decoding may be used.

For example, the error detection and correction circuit 126 may detect an error bit by the unit of a set sector in each of the read data, when each read data is constituted by a plurality of sectors. A sector may mean a data unit that is smaller than a page, which is the read unit of a flash memory. Sectors constituting each read data may be matched with one another using an address.

The error detection and correction circuit 126 may calculate a bit error rate (BER), and may determine whether an error is correctable or not, by sector units. For example, when a bit error rate is higher than a reference value, the error detection and correction circuit 126 may determine that a corresponding sector is uncorrectable or has failed. On the other hand, when a bit error rate is lower than the reference value, the error detection and correction circuit 126 may determine that a corresponding sector is correctable or has passed.

The error detection and correction circuit 126 may perform an error detection and correction operation sequentially for all read data. In the case where a sector included in read data is correctable, the error detection and correction circuit 126 may omit an error detection and correction operation for a corresponding sector for next read data. If the error detection and correction operation for all read data is ended in this way, then the error detection and correction circuit 126 may detect a sector which is uncorrectable in read data last. There may be one or more sectors that are determined to be uncorrectable. The error detection and correction circuit 126 may transfer information (e.g., address information) regarding a sector which is determined to be uncorrectable to the processor 124.

A bus 127 may be configured to provide channels among the components 121, 122, 124, 125, and 126 of the controller 120. The bus 127 may include, for example, a control bus for transferring various control signals, commands and the like, a data bus for transferring various data, and so forth.

Some components among the above-described components 121, 122, 124, 125, and 126 of the controller 120 may be omitted, or some components among the above-described components 121, 122, 124, 125, and 126 of the controller 120 may be integrated into one component. In addition to the above-described components 121, 122, 124, 125, and 126 of the controller 120, one or more other components may be added.

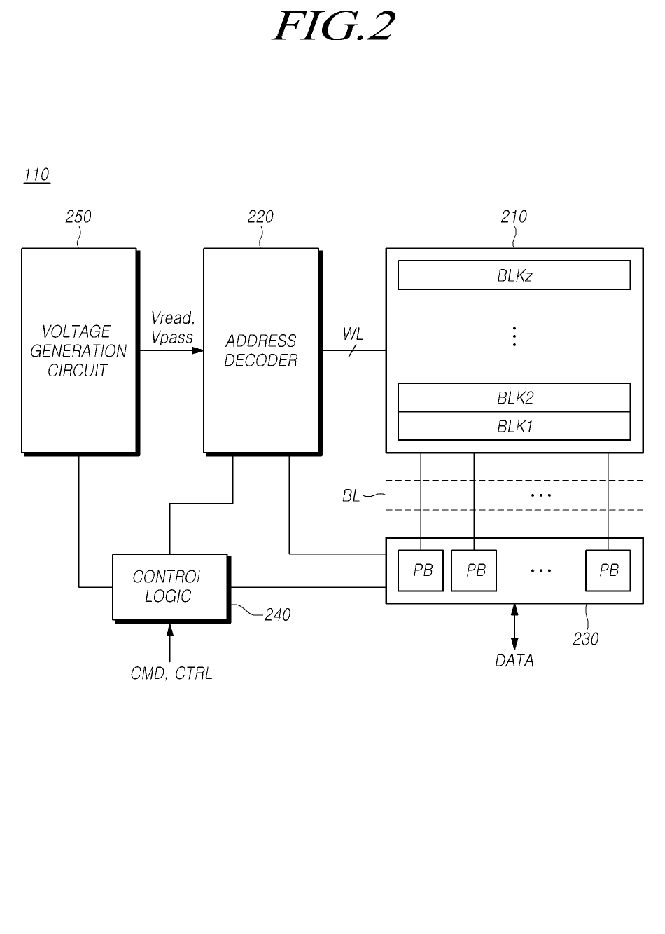

Hereinbelow, the memory 110 will be described in further detail with reference to FIG. 2.

FIG. 2 illustrates the memory 110 of FIG. 1.

Referring to FIG. 2, the memory 110 may include a memory cell array 210, an address decoder 220, a read and write circuit 230, a control logic 240, and a voltage generation circuit 250.

The memory cell array 210 may include a plurality of memory blocks BLK1 to BLKz (where z is a natural number of 2 or greater).

In the plurality of memory blocks BLK1 to BLKz, a plurality of word lines WL and a plurality of bit lines BL may be disposed, and a plurality of memory cells may be arranged.

The plurality of memory blocks BLK1 to BLKz may be coupled with the address decoder 220 through the plurality of word lines WL. The plurality of memory blocks BLK1 to BLKz may be coupled with the read and write circuit 230 through the plurality of bit lines BL.

Each of the plurality of memory blocks BLK1 to BLKz may include a plurality of memory cells. For example, the plurality of memory cells may be nonvolatile memory cells, and may be configured by nonvolatile memory cells that have vertical channel structures.

The memory cell array 210 may be configured by a memory cell array of a two-dimensional structure or may be configured by a memory cell array of a three-dimensional structure.

Each of the plurality of memory cells included in the memory cell array 210 may store at least 1-bit data. For instance, each of the plurality of memory cells included in the memory cell array 210 may be a single level cell (SLC) that stores 1-bit data. In another instance, each of the plurality of memory cells included in the memory cell array 210 may be a multi-level cell (MLC) that stores 2-bit data. In still another instance, each of the plurality of memory cells included in the memory cell array 210 may be a triple level cell (TLC) that stores 3-bit data. In yet another instance, each of the plurality of memory cells included in the memory cell array 210 may be a quad level cell (QLC) that stores 4-bit data. In a further instance, the memory cell array 210 may include a plurality of memory cells, each of which stores 5 or more-bit data.

The number of bits of data stored in each of the plurality of memory cells may be dynamically determined. For example, a single-level cell that stores 1-bit data may be changed to a triple-level cell that stores 3-bit data.

Referring to FIG. 2, the address decoder 220, the read and write circuit 230, the control logic 240 and the voltage generation circuit 250 may operate as a peripheral circuit that drives the memory cell array 210.

The address decoder 220 may be coupled to the memory cell array 210 through the plurality of word lines WL.

The address decoder 220 may be configured to operate in response to the control of the control logic 240.

The address decoder 220 may receive an address through an input/output buffer in the memory 110. The address decoder 220 may be configured to decode a block address in the received address. The address decoder 220 may select at least one memory block depending on the decoded block address.

The address decoder 220 may receive a read voltage Vread and a pass voltage Vpass from the voltage generation circuit 250.

The address decoder 220 may apply the read voltage Vread to a selected word line WL in a selected memory block during a read operation, and may apply the pass voltage Vpass to the remaining unselected word lines WL.

The address decoder 220 may apply a verify voltage generated in the voltage generation circuit 250 to a selected word line WL in a selected memory block in a program verify operation, and may apply the pass voltage Vpass to the remaining unselected word lines WL.

The address decoder 220 may be configured to decode a column address in the received address. The address decoder 220 may transmit the decoded column address to the read and write circuit 230.

A read operation and a program operation of the memory 110 may be performed by the unit of a page. An address received when a read operation or a program operation is requested may include at least one from among a block address, a row address and a column address.

The address decoder 220 may select one memory block and one word line depending on a block address and a row address. A column address may be decoded by the address decoder 220 and be provided to the read and write circuit 230.

The address decoder 220 may include at least one from among a block decoder, a row decoder, a column decoder and an address buffer.

The read and write circuit 230 may include a plurality of page buffers PB. The read and write circuit 230 may operate as a read circuit in a read operation of the memory cell array 210, and may operate as a write circuit in a write operation of the memory cell array 210.

The read and write circuit 230 described above may also be referred to as a page buffer circuit or a data register circuit that includes a plurality of page buffers PB. The read and write circuit 230 may include data buffers that take charge of a data processing function, and may further include cache buffers that take charge of a caching function.

The plurality of page buffers PB may be coupled to the memory cell array 210 through the plurality of bit lines BL. The plurality of page buffers PB may continuously supply sensing current to bit lines BL coupled with memory cells to sense threshold voltages (Vth) of the memory cells in a read operation and a program verify operation, and may latch sensing data by sensing, through sensing nodes, changes in the amounts of current flowing, depending on the programmed states of the corresponding memory cells.

The read and write circuit 230 may operate in response to page buffer control signals output from the control logic 240.

In a read operation, the read and write circuit 230 temporarily stores read data by sensing data of memory cells, and then, outputs data DATA to the input/output buffer of the memory 110. As an exemplary embodiment, the read and write circuit 230 may include a column select circuit in addition to the page buffers PB or the page registers.

The control logic 240 may be coupled with the address decoder 220, the read and write circuit 230 and the voltage generation circuit 250. The control logic 240 may receive a command CMD and a control signal CTRL through the input/output buffer of the memory 110.

The control logic 240 may be configured to control general operations of the memory 110 in response to the control signal CTRL. The control logic 240 may output control signals for adjusting the precharge potential levels of the sensing nodes of the plurality of page buffers PB.

The control logic 240 may control the read and write circuit 230 to perform a read operation of the memory cell array 210. The voltage generation circuit 250 may generate the read voltage Vread and the pass voltage Vpass used in a read operation, in response to a voltage generation circuit control signal output from the control logic 240.

Each memory block of the memory 110 described above may be configured by a plurality of pages corresponding to a plurality of word lines WL and a plurality of strings corresponding to a plurality of bit lines BL.

In a memory block BLK, a plurality of word lines WL and a plurality of bit lines BL may be disposed to intersect with each other. For example, each of the plurality of word lines WL may be disposed in a row direction, and each of the plurality of bit lines BL may be disposed in a column direction. In another example, each of the plurality of word lines WL may be disposed in a column direction, and each of the plurality of bit lines BL may be disposed in a row direction.

A memory cell may be coupled to one of the plurality of word lines WL and one of the plurality of bit lines BL. A transistor may be disposed in each memory cell.

For example, a transistor disposed in each memory cell may include a drain, a source, and a gate. The drain (or source) of the transistor may be coupled with a corresponding bit line BL directly or via another transistor. The source (or drain) of the transistor may be coupled with a source line (which may be the ground) directly or via another transistor. The gate of the transistor may include a floating gate, which is surrounded by a dielectric, and a control gate to which a gate voltage is applied from a word line WL.

In each memory block, a first select line (also referred to as a source select line or a drain select line) may be additionally disposed outside a first outermost word line more adjacent to the read and write circuit 230 between two outermost word lines, and a second select line (also referred to as a drain select line or a source select line) may be additionally disposed outside a second outermost word line between the two outermost word lines.

At least one dummy word line may be additionally disposed between the first outermost word line and the first select line. At least one dummy word line may also be additionally disposed between the second outermost word line and the second select line.

A read operation and a program operation (or write operation) of the memory block described above may be performed by the unit of a page, and an erase operation may be performed by the unit of a memory block.

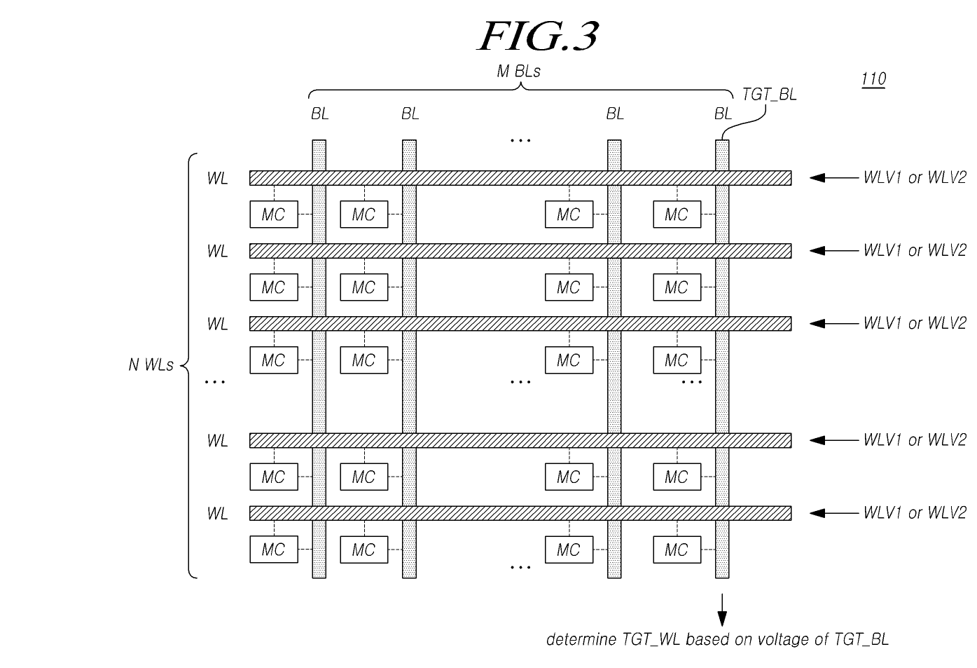

FIG. 3 illustrates a schematic operation of the memory 110 according to an embodiment of the present disclosure.

Referring to FIG. 3, the memory 110 may include N word lines WL (where N is a natural number equal to or greater than 2) and M bit lines BL (where M is a natural number equal to or greater than 2). The N word lines WL and the M bit lines BL may be included in a memory block included in the memory 110.

The memory 110 may include a plurality of memory cells MC. The plurality of memory cells MC may respectively correspond to one of the N word lines WL and one of the M bit lines BL. Accordingly, each memory cell may be identified by one word line and one bit line.

That a memory cell corresponds to one word line and one bit line means that the memory cell may be electrically connected to the corresponding word line and bit line through one or more elements (e.g., electrical wiring or transistors).

Each of the plurality of memory cells MC may store at least one bit of data. The number of bits stored in each memory cell may be dynamically determined.

The memory 110 may apply a first word line voltage WLV1 or a second word line voltage WLV2 to each of the N word lines WL. In this case, the magnitude of the first word line voltage WLV1 is greater than that of the second word line voltage WLV2.

The memory 110 may determine a target word line TGT_WL. The target word line TGT_WL is a word line WL that is the last programmed word line among the N word lines WL. Thus, the last programmed memory cell (or a set of memory cells) is connected to the target word line TGT_WL.

The memory 110 may perform program operations on the N word lines WL sequentially in a preset order. If the program operation is interrupted after programming the k-th word line among the N word lines WL, the first to k-th word lines may be programmed word lines, and the (k+1)-th to N-th word lines may be open word lines. The memory cells connected to the open word lines may all be in an erased state.

The memory 110 may determine the target word line TGT_WL based on a voltage of a target bit line TGT_BL under the condition where a first word line voltage WLV1 or a second word line voltage WLV2 is applied to each of the N word lines WL.

The target bit line TGT_BL is not used for writing data from outside the memory 110. Instead, the target bit line TGT_BL may be reserved for determining the target word line TGT_WL. The target bit line TGT_BL may be a dedicated bit line which is reserved for determining the target word line TGT_WL or an unused bit line that is not used during the reading or writing process. In this case, a memory cell corresponding to the target bit line TGT_BL may not be accessible from outside the memory 110.

One or more memory cells may correspond to (i.e., connected to) the target bit line TGT_BL. In an embodiment, as shown in FIG. 3, N numbers of memory cells are connected to the target bit line TGT_BL. In another embodiment, however, the total number of memory cells corresponding to (i.e., connected to) the target bit line TGT_BL may be less than N.

The memory 110 may use the target bit line TGT_BL only when determining the target word line TGT_WL, and may prohibit a given data, which is transmitted from outside the memory 110 to the memory cell, from being written in the target bit line TGT_BL.

In such way, the memory 110 may determine the target word line TGT_WL independently (standalone). Thus, according to the present disclosure, a process to identify a target word line TGT_WL can be performed without the repeated process of reading out memory cells in a given area of the memory 110. According to the present disclosure, the process to determine a target word line TGT_WL can be performed by reading out a portion of the memory cells in the given area. Put it differently, the present invention can forgo the repeated process of reading out all memory cells of the given area of the memory 110 in the course of searching a target word line TGT_WL. As a result, the memory 110 may determine the target word line TGT_WL more efficiently and more rapidly.

Meanwhile, the operation for determining the target word line TGT_WL may be performed by various modules. For example, the operation for determining the target word line TGT_WL may be performed by the control logic 240 described in FIG. 2. In another example, the operation may be performed by a separate arithmetic circuit (e.g., an ASIC, an FPGA, or a microprocessor) included in the memory 110.

Hereinafter, an example will be described in which the control logic 240 included in the memory 110 performs the operation for determining the target word line TGT_WL.

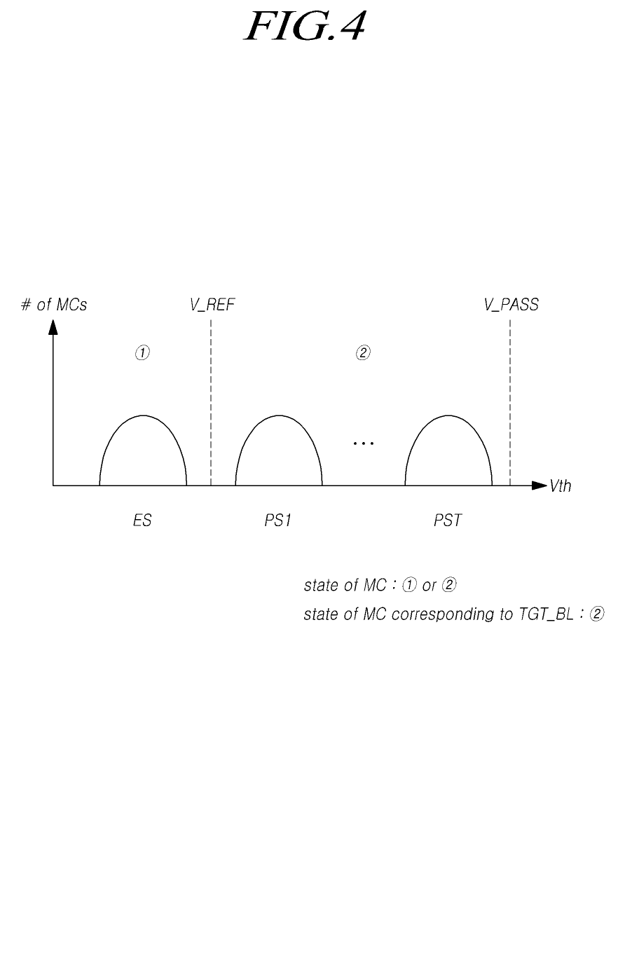

FIG. 4 illustrates states of memory cells MC according to an embodiment of the present disclosure.

Referring to FIG. 4, each of the plurality of memory cells MC may be in an erased state ES or one of T programmed states PS1 through PST (where T is a natural number). For example, when each memory cell is a single-level cell, T = 1; when it is a multi-level cell, T = 3; and when it is a triple-level cell, T = 7.

The threshold voltage Vth of memory cells in an erased state ES among the plurality of memory cells MC may be equal to or less than a preset reference voltage V_REF. The reference voltage V_REF may be a voltage used to determine whether a given memory cell MC is in the erased state ES.

For example, if the state of a given memory cell has a threshold voltage lower than the reference voltage V_REF, then the given memory cell may be determined to be in an erased state ES. If the state of a given memory cell has a threshold voltage higher than the reference voltage V_REF, then the given memory cell may be determined to be in a programmed state. The programmed state may be PST (where T is a natural number) such as PS1, PS3, PS7, etc.

The threshold voltage Vth of the programmed memory cell MC may be equal to or less than the aforementioned pass voltage V_PASS.

In embodiments of the present disclosure, a memory cell corresponding to (i.e., connected to) the target bit line TGT_BL may have a programmed state, such as PS1, PS3, PS7, etc.. That is, the memory cell corresponding to (i.e., connected to) the target bit line TGT_BL is not in the erased state.

Meanwhile, the first word line voltage WLV1 described in FIG. 3 may be the pass voltage V_PASS, and the second word line voltage WLV2 may be the reference voltage V_REF.

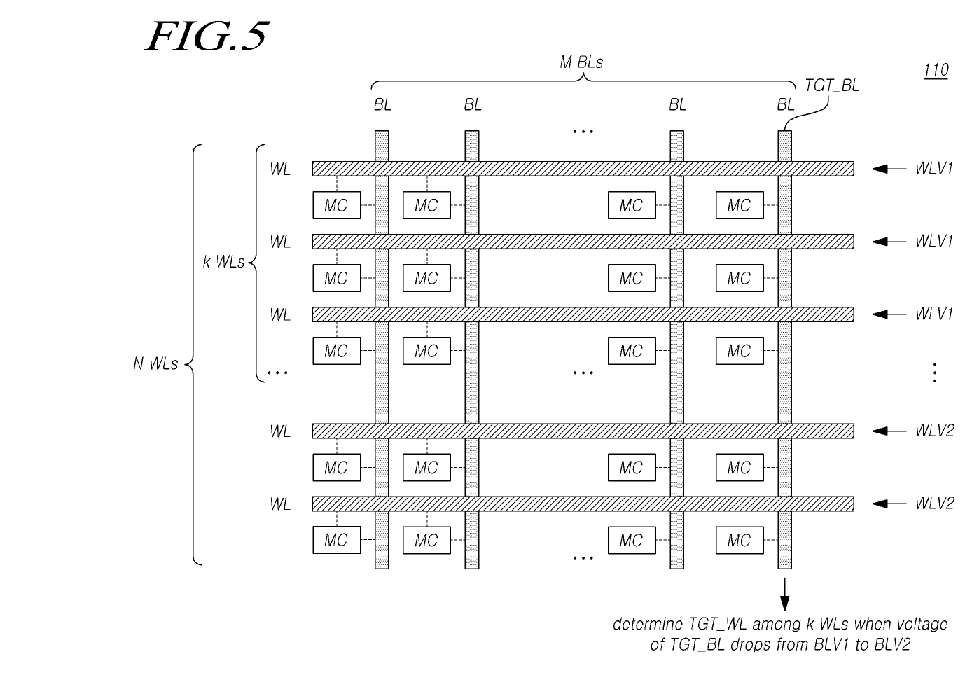

FIG. 5 illustrates a schematic operation in which the memory 110 determines the target word line TGT_WL according to an embodiment of the present disclosure.

Referring to FIG. 5, the control logic 240 of the memory 110 may determine whether a voltage of the target bit line TGT_BL falls from a first bit line voltage BLV1 to a second bit line voltage BLV2, in a state where the first word line voltage WLV1 is applied to k word lines (where k is a natural number) among the N word lines WL and the second word line voltage WLV2 is applied to the remaining (N − k) word lines.

For example, the control logic 240 may apply the first word line voltage WLV1 to the first to k-th word lines among the N word lines WL.

As described above, program operations for the N word lines WL may be performed sequentially in a preset order. In this case, the order of the N word lines WL may be determined in various ways. For example, the order of the N word lines WL may be determined in ascending or descending order of index values assigned to the respective N word lines WL.

When the voltage of the target bit line TGT_BL falls from the first bit line voltage BLV1 to the second bit line voltage BLV2, the control logic 240 may determine the target word line TGT_WL among the k word lines to which the first word line voltage WLV1 is applied.

For example, the control logic 240 may determine the k-th word line among the N word lines WL as the target word line TGT_WL.

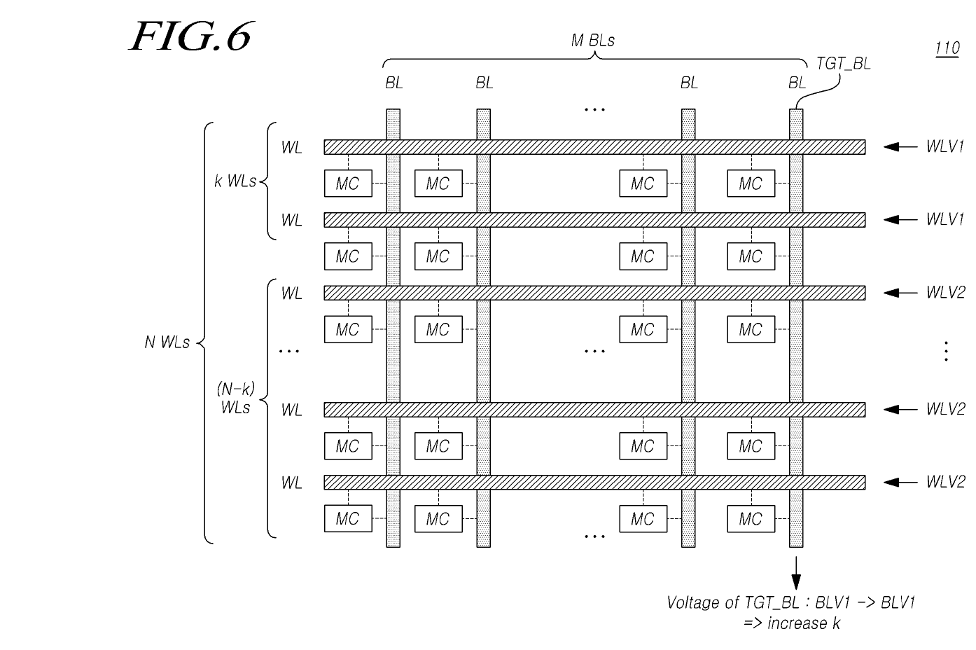

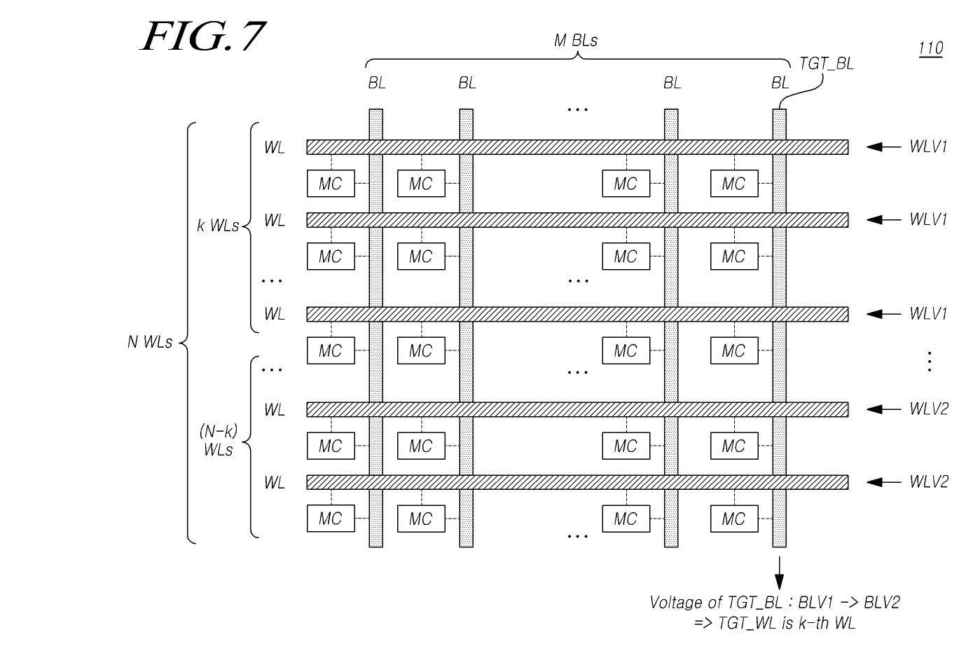

Hereinafter, this will be described in more detail with reference to FIGS. 6 and 7.

FIGS. 6 and 7 illustrate an example of an operation for determining the target word line TGT_WL by the memory 110 according to an embodiment of the present disclosure.

Referring first to FIG. 6, the control logic 240 of the memory 110 may detect that the voltage of the target bit line TGT_BL remains at the first bit line voltage BLV1 when the first word line voltage WLV1 is applied to k numbers of word lines (where k is a natural number), e.g., the 1^{st} to k^{th} word lines, and the second word line voltage WLV2 is applied to the remaining (N − k) numbers of word lines, e.g., (k+1)^{th} to N^{th} word lines. Here, the number k may be determined arbitrarily between the number 1 through N. For example, the number k may be N/2.

When the voltage of the target bit line TGT_BL is unchanged, i.e., remains at the first bit line voltage BLV1, the control logic 240 determines that none of the 1^{st} to k^{th} word lines is the target word line TGT_WL. Then, the control logic 240 increases the value of k to repeat the search for the target word line TGT_WL. That is, the first word line voltage WLV1 is applied to (k+1) numbers of word lines, e.g., the 1^{st} to (k+1)^{th} word lines. Then, the control logic 240 again determines whether the voltage of the target bit line TGT_BL drops from the first bit line voltage BLV1 to the second bit line voltage BLV2. The control logic 240 may repeatedly perform the above-described process to search for the target word line TGT_WL until the voltage of the target bit line TGT_BL drops from the first bit line voltage BLV1 to the second bit line voltage BLV2.

Referring to FIG. 7, the control logic 240 of the memory 110 seeks to determine when the voltage of the target bit line TGT_BL drops from the first bit line voltage BLV1 to the second bit line voltage BLV2 when the first word line voltage WLV1 is applied to k numbers of word lines , i.e., the 1^{st} to k^{th} word lines and the second word line voltage WLV2 is applied to the remaining (N − k) numbers of word lines, i.e., (k+1)^{th} to N^{th} word lines.

In FIG. 7, the control logic 240 determines the k-th word line among the N word lines WL as the target word line TGT_WL when the voltage of TGT_BL satisfies a voltage drop from BLV1 to BLV2.

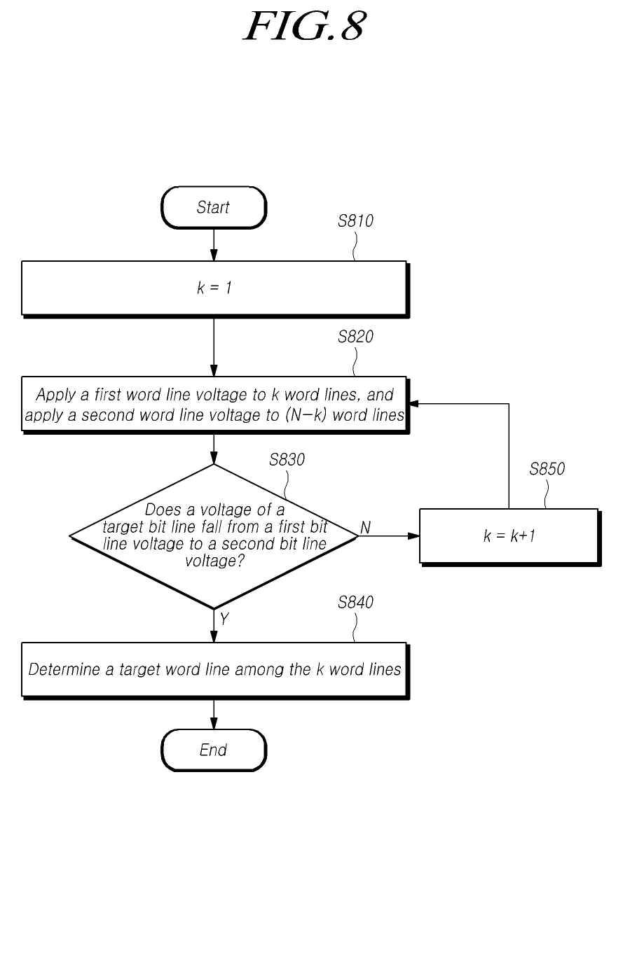

Hereinafter, the operation for determining the target word line TGT_WL by the memory 110 may be represented by a flowchart as shown in FIG. 8.

FIG. 8 is a flowchart illustrating an example of an operation for determining the target word line TGT_WL by the memory 110 according to an embodiment of the present disclosure.

Referring to FIG. 8, the memory 110 may initialize the value of k to 1 (S810).

Then, the memory 110 may apply the first word line voltage WLV1 to a k number of word lines among the N number of word lines WL, i.e., the 1^{st} through the k^{th} word lines, and apply the second word line voltage WLV2 to the remaining (N − k) number of word lines (S820), i.e., the (k+1)^{th} through the N^{th} word lines.

Thereafter, the memory 110 determines whether the voltage of the target bit line TGT_BL, from among the M bit lines BL, falls from the first bit line voltage BLV1 to the second bit line voltage BLV2 (S830).

When the voltage of the target bit line TGT_BL falls from the first bit line voltage BLV1 to the second bit line voltage BLV2 (S830-Y), the memory 110 may determine the target word line TGT_WL among the k word lines to which the first word line voltage WLV1 has been applied (S840). For example, the memory 110 may determine the k-th word line among the k word lines as the target word line TGT_WL.

On the other hand, when the voltage of the target bit line TGT_BL remains at the first bit line voltage BLV1 (S830-N), the memory 110 may increase the value of k by 1 (S850), and may repeat step S820.

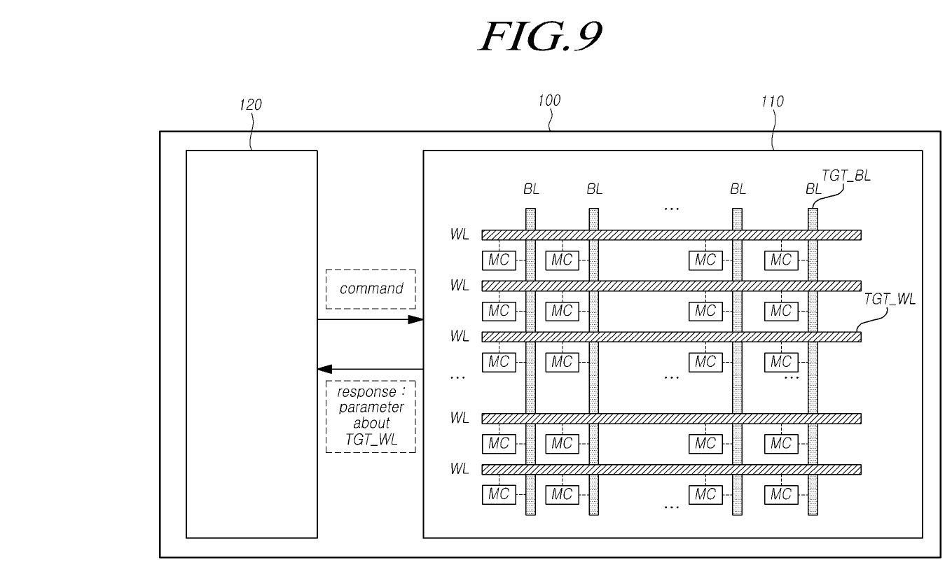

FIG. 9 illustrates a schematic operation of a storage device 100 according to an embodiment of the present disclosure.

Referring to FIG. 9, the storage device 100 may include the memory 110 and the controller 120. The memory 110 may perform the operations described above with reference to FIGS. 3 through 8.

The controller 120 may transmit a command requesting information about the target word line TGT_WL.

In response to the command received from the controller 120, the memory 110 may determine the target word line TGT_WL and may transmit a parameter indicating information about the target word line TGT_WL to the controller 120.

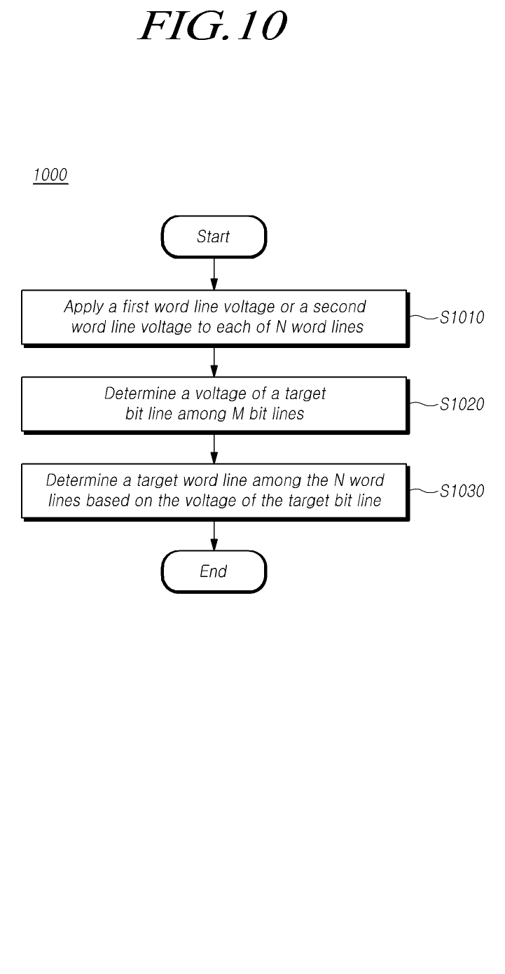

FIG. 10 illustrates a method of operating the memory 110 according to an embodiment of the present disclosure.

Referring to FIG. 10, the method of operating the memory 110 may include a step (S1010) of applying a first word line voltage WLV1 or a second word line voltage WLV2 to each of an N number of word lines WL.

For example, in step S1010, the first word line voltage WLV1 may be applied to the first to k-th word lines among the N number of word lines WL.

The method of operating the memory 110 may further include a step (S1020) of determining a voltage of a target bit line TGT_BL among M bit lines BL.

The memory 110 may include an N number of word lines WL, an M number of bit lines BL, and memory cells MC. Each of the memory cells MC is coupled to one of the N number of word lines WL and one of the M number of bit lines BL.

For example, each of the plurality of memory cells MC may be in an erased state ES or one of T programmed states PS1 through PST. In this case, the memory cell corresponding to the target bit line TGT_BL among the plurality of memory cells MC may be in one of the T programmed states PS1 through PST.

For example, the first word line voltage WLV1 may be a pass voltage V_PASS, and the second word line voltage WLV2 may be a reference voltage V_REF. As mentioned above, the reference voltage V_REF is used to determine whether each of the plurality of memory cells MC is in an erased state.

The method of operating the memory 110 may further include a step (S1030) of determining, based on the voltage of a target bit line TGT_BL, a target word line TGT_WL, which is a word line programmed the last among the N word lines WL.

For example, in step S1030, if the voltage of the target bit line TGT_BL falls from the first bit line voltage BLV1 to the second bit line voltage BLV2 in a state where the first word line voltage WLV1 is applied to k numbers of word lines, e.g., the 1^{st} word line through the k^{th} word line, and the second word line voltage WLV2 is applied to the remaining (N − k) numbers of word lines among the N word lines WL, e.g., the (k+1)^{th} word line through the N^{th} word line, then the target word line TGT_WL may be determined from among the 1^{st} word line through the k^{th} word line to which the first word line voltage WLV1 has been applied.

In this case, in step S1030, the k-th word line among the N word lines WL may be determined as the target word line TGT_WL when the voltage of the target bit line TGT_BL falls from the first bit line voltage BLV1 to the second bit line voltage BLV2.

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A memory comprising:
an N number of word lines;
an M number of bit lines;
a plurality of memory cells respectively corresponding to one of the N number of word lines and one of the M number of bit lines; and
a control logic determining a target word line, wherein the target word line is a word line programmed last from among the N number of word lines,
wherein the control logic determines the target word line based on a voltage of a target bit line when a first word line voltage or a second word line voltage is applied to each of the N number of word lines,
and
wherein each of N and M is a natural number equal to or greater than 2.

2. The memory of claim 1,
wherein each of the plurality of memory cells is in either an erased state or a programmed state,
wherein a memory cell among the plurality of memory cells is connected to the target bit line and in the programmed state, and
wherein a possible number of the programmed state of a given memory cell, which is selected among the memory cells, is T,
wherein T is a natural number.

3. The memory of claim 2,
wherein the first word line voltage is a pass voltage,
wherein the second word line voltage is a reference voltage, and
wherein the reference voltage is used to determine whether each of the plurality of memory cells is in the erased state.

4. The memory of claim 1,
wherein when a voltage of the target bit line drops from a first bit line voltage to a second bit line voltage, the first word line voltage is applied to a k number of word lines among the N number of word lines and the second word line voltage is applied to the remaining (N−k) number of word lines; and
when the voltage of the target bit line drops from the first bit line voltage to the second bit line voltage, the memory determines the target word line among the k number of word lines to which the first word line voltage is applied, and
wherein k is a natural number between 1 through N.

5. The memory of claim 4,
wherein the first word line voltage is applied to first to k-th word lines among the N number of word lines.

6. The memory of claim 5,
wherein the control logic determines the k-th word line among the N number of word lines as the target word line.

7. A storage device comprising:
a memory comprising N number of word lines, M number of bit lines, and a plurality of memory cells respectively corresponding to one of the N number of word lines and one of the M number of bit lines, the memory determining a target word line, wherein the target word line is a word line programmed last from among the N number of word lines; and
a controller for transmitting a command requesting information about the target word line to the memory,
wherein the memory:
determines the target word line based on a voltage of a target bit line when a first word line voltage or a second word line voltage is applied to each of the N number of word lines; and
transmits a parameter indicating the information about the target word line to the controller in response to the command, and
wherein each of N and M is a natural number equal to or greater than 2.

8. The storage device of claim 7,
wherein each of the plurality of memory cells is in either an erased state or a programmed state,
wherein a memory cell among the plurality of memory cells is connected to the target bit line and in the programmed state, and
wherein a possible number of the programmed state of a given memory cell, which is selected among the plurality of memory cells, is T,
wherein T is a natural number.

9. The storage device of claim 8,
wherein the first word line voltage is a pass voltage,
wherein the second word line voltage is a reference voltage, and
wherein the reference voltage is used to determine whether each of the plurality of memory cells is in the erased state.

10. The storage device of claim 7,
wherein the memory prohibits writing data requested by the controller into a memory cell connected to the target bit line.

11. The storage device of claim 7,
wherein:
when a voltage of the target bit line drops from a first bit line voltage to a second bit line voltage, the first word line voltage is applied to a k number of word lines among the N number of word lines and the second word line voltage is applied to the remaining (N−k) number of word lines; and
when the voltage of the target bit line drops from the first bit line voltage to the second bit line voltage, the memory determines the target word line among the k number of word lines to which the first word line voltage is applied,
wherein k is a natural number between 1 through N.

12. The storage device of claim 11,
wherein the memory applies the first word line voltage to first to k-th word lines among the N number of word lines.

13. The storage device of claim 12,
wherein the memory determines the k-th word line among the N number of word lines as the target word line.

14. A method of operating a memory comprising N number of word lines, M number of bit lines, and a plurality of memory cells respectively corresponding to one of the N number of word lines and one of the M number of bit lines, the method comprising:
applying a first word line voltage or a second word line voltage to each of the N number of word lines;
determining a voltage of a target bit line among the M number of bit lines; and
determining a target word line, wherein the target word line is a word line programmed last from among the N number of word lines, based on the voltage of the target bit line,
wherein each N and M is a natural number equal to or greater than 2.

15. The method of claim 14,
wherein each of the plurality of memory cells is in either an erased state or a programmed state,
wherein a memory cell among the plurality of memory cells is connected to the target bit line and in the programmed state, and
wherein a possible number of the programmed state of a given memory cell, which is selected among the memory cells, is T,
wherein T is a natural number.

16. The method of claim 15,
wherein the first word line voltage is a pass voltage,
wherein the second word line voltage is a reference voltage, and
wherein the reference voltage is used to determine whether each of the plurality of memory cells is in the erased state.

17. The method of claim 14,
wherein determining the target word line comprises:
when the voltage of the target bit line drops from a first bit line voltage to a second bit line voltage, the first word line voltage is applied to a k number of word lines among the N number of word lines and the second word line voltage is applied to the remaining (N−k) number of word lines, determining the target word line among the k number of word lines to which the first word line voltage is applied, and
wherein k is a natural number.

18. The method of claim 17,
wherein applying the first word line voltage or the second word line voltage to each of the N number of word lines comprises applying the first word line voltage to first to k-th word lines among the N number of word lines.

19. The method of claim 18,
wherein determining the target word line comprises determining the k-th word line among the N number of word lines as the target word line.
